(19) United States
(12) Patent Application Publication
(10) Pub. No.: US 2019/0253676 A1
(43) Pub. Date: Aug. 15, 2019

(54) ILLUMINATION SYSTEM AND PROJECTION APPARATUS

(71) Applicant: Coretronic Corporation, Hsin-Chu (TW)

(72) Inventors: CHIH-HSIEN TSAI, Hsin-Chu (TW); HSIN-YUEH CHANG, Hsin-Chu (TW); YI-HSUANG WENG, Hsin-Chu (TW); JO-HAN HSU, Hsin-Chu (TW); CHI-TANG HSIEH, Hsin-Chu (TW)

(21) Appl. No.: 16/262,966

(22) Filed: Jan. 31, 2019

(30) Foreign Application Priority Data
Feb. 9, 2018 (CN) 201810153142.X

(51) Int. Cl. H04N 9/31; G02B 27/09; H01L 33/50

(52) U.S. Cl. CPC H04N 9/3111; H01L 33/50; G02B 27/0961

(57) ABSTRACT

An illumination system includes an exciting light source module, a dichroic element, a wavelength-converting element, a light homogenizing element and a lens array. The exciting light source module includes a plurality of exciting light sources, each for providing an exciting beam. The dichroic element allows the exciting beam to be transmitted to the wavelength-converting element. The wavelength-converting element converts the exciting beam into a converted beam and reflects the converted beam to the dichroic element, and the dichroic element transmits the converted beam to the light homogenizing element. The light homogenizing element has a light incident end. The lens array includes a plurality of lens units, and a long side of each of the lens units is parallel to a long side of the light incident end when being projected along the transmission path of the converted beam to the light incident end.

### CROSS-REFERENCE TO RELATED APPLICATION

THIS APPLICATION CLAIMS THE PRIORITY BENEFIT OF CHINA APPLICATION (CN201810153142.X FILED ON 2018 Feb. 9). THE ENTIRETY OF THE ABOVE-MENTIONED PATENT APPLICATION IS HEREBY INCORPORATED BY REFERENCE HEREIN AND MADE A PART OF THIS SPECIFICATION.

### FIELD OF THE INVENTION

The invention relates to a display apparatus, and more particularly to an illumination system and a projection apparatus using the same.

### BACKGROUND OF THE INVENTION

With the requirements of market on the brightness, color saturation, service life, non-toxic environmental protection and so on of projection apparatus, the type of light source used by the projection apparatus is evolved from UHP lamp, light emitting diode (LED) to the laser diode (LD).

In the conventional projection apparatus using a laser diode, the laser diode provides an exciting beam to excite the phosphor layer on the phosphor wheel to generate a fluorescent beam, and then the fluorescent beam is homogenized by a light homogenizing element. However, the light incident end of the light homogenizing element is rectangular, and the light spot formed on the phosphor wheel by the exciting beam is a circular light spot, and the excited fluorescent beam forms a corresponding circular light spot at the light incident end of the light homogenizing element. Due to the shape of the light spot formed by the fluorescent beam at the light incident end does not match the shape of the light incident end, the light utilization efficiency is poor, thereby reducing the brightness of the projection apparatus.

The information disclosed in this “BACKGROUND OF THE INVENTION” section is only for enhancement understanding of the background of the invention and therefore it may contain information that does not form the prior art that is already known to a person of ordinary skill in the art. Furthermore, the information disclosed in this “BACKGROUND OF THE INVENTION” section does not mean that one or more problems to be solved by one or more embodiments of the invention were acknowledged by a person of ordinary skill in the art.

### SUMMARY OF THE INVENTION

The invention provides an illumination system that can improve light utilization efficiency.

The invention provides a projection apparatus that can improve light utilization efficiency.

Other objectives and advantages of the invention can be further understood from the technical features disclosed by the invention.

In order to achieve one or partial or all of the above purposes or other purposes, an illumination system provided by an embodiment of the invention includes an exciting light source module, a dichroic element, a wavelength-converting element, a light homogenizing element and a lens array. The exciting light source module includes a plurality of exciting light sources, and each of the exciting light sources is used to provide an exciting beam. The dichroic element is disposed on a transmission path of the exciting beam and used to allow the exciting beam from the exciting light source module to be transmitted to the wavelength-converting element. The wavelength-converting element is disposed on a transmission path of the exciting beam from the dichroic element to convert the exciting beam into a converted beam and reflect the converted beam to the dichroic element, and the dichroic element is used to transmit the converted beam to the light homogenizing element. The light homogenizing element is disposed on a transmission path of the converted beam from the dichroic element, and the light homogenizing element has a light incident end. The lens array is disposed on a transmission path of the exciting beam. The lens array includes a plurality of lens units, and a long side of each of the lens units is parallel to a long side of the light incident end when being projected along the transmission path of the converted beam to the light incident end.

In order to achieve one or partial or all of the above purposes or other purposes, a projection apparatus provided by an embodiment of the invention includes the aforementioned illumination system, a light valve and a projection lens. The illumination system described above is used to provide an illumination beam. The light valve is disposed on a transmission path of the illumination beam to convert the illumination beam into an image beam. The projection lens is disposed on a transmission path of the image beam.

In summary, in the embodiment of the invention, since a lens array is adopted, the shape of light spot when the exciting beam exiting the lens array is irradiated to the wavelength-converting element can be adjusted, so that the shape of the light spot of the converted beam converted by the wavelength-converting element corresponds to the shape of the light incident end of the light homogenizing element, thereby improving the light utilization efficiency. The projection apparatus of the embodiment of the invention can improve the light utilization efficiency because of using the above illumination system.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an illumination system according to an embodiment of the invention;

FIG. 2 is a schematic diagram of a light incident end of the light homogenizing element in FIG. 1;

FIG. 3 is a schematic diagram of light spots formed by the exciting beam in the lens array according to an embodiment of the invention;

FIG. 4 is a schematic diagram of a light spot of an exciting beam and a converted beam on a wavelength-converting element according to an embodiment of the invention;

FIG. 5 is a schematic diagram of an illumination system according to another embodiment of the invention;

FIG. 6 is a block diagram of a projection apparatus according to an embodiment of the invention; and

FIG. 7 is a schematic diagram of a light homogenizing element and a light valve according to an embodiment of the invention.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

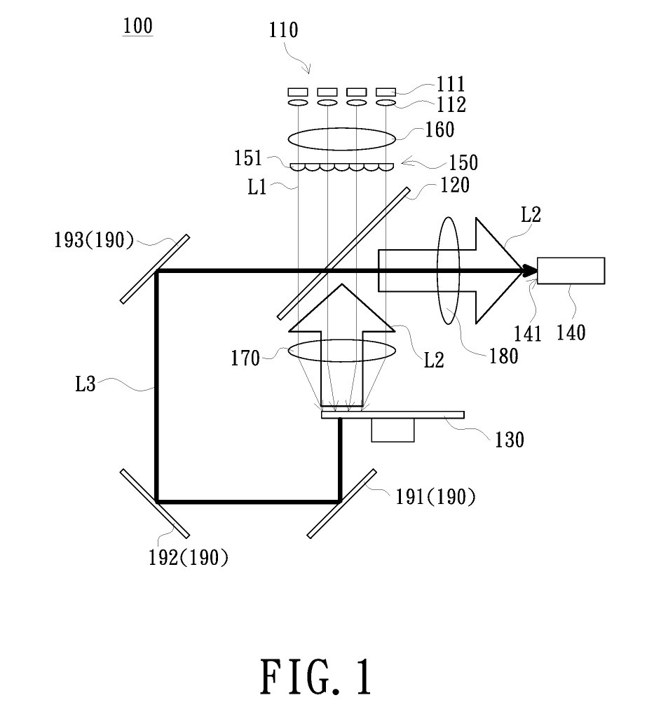

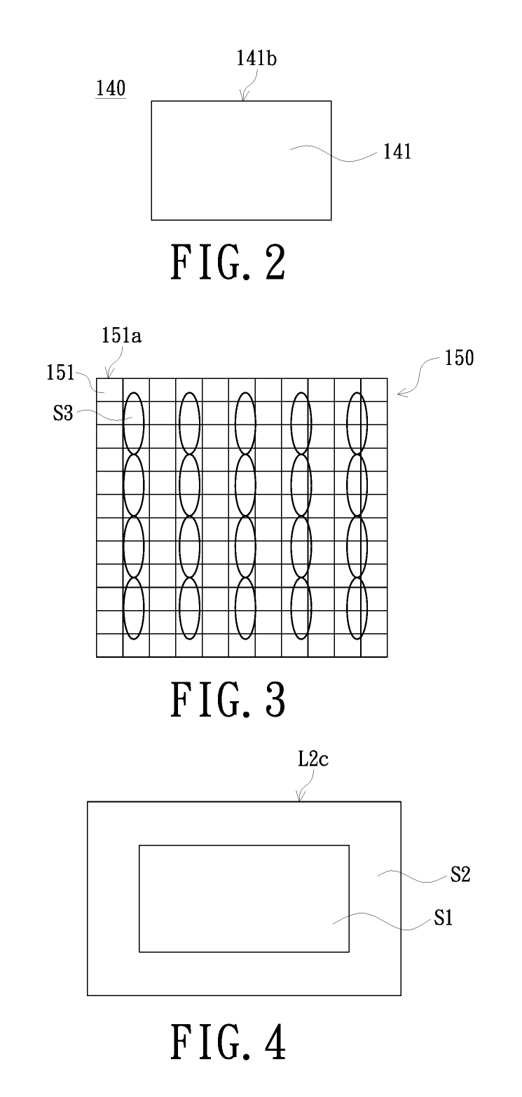

FIG. 1 is a schematic diagram of an illumination system according to an embodiment of the invention. Referring to FIGS. 1 and 2, the illumination system 100 of the embodiment includes an exciting light source module 110, a dichroic element 120, a wavelength-converting element 130, a light homogenizing element 140 and a lens array 150. The exciting light source module 110 includes a plurality of exciting light sources 111, and each exciting light source 111 is used to provide an exciting beam L1. The dichroic element 120 is disposed on the transmission path of the exciting beams L1, and is used to allow the exciting beams L1 from the exciting light source module 110 to be transmitted to the wavelength-converting element 130. The wavelength-converting element 130 is disposed on the transmission path of the exciting beams L1 from the dichroic element 120 to convert the exciting beams L1 into a converted beam L2 and reflect the converted beam L2 to the dichroic element 120, wherein the wavelength of the exciting beam L1 is different from the wavelength of the converted beam L2. The dichroic element 120 is used to transmit the converted beam L2 to the light homogenizing element 140. The light homogenizing element 140 is disposed on the transmission path of the converted beam L2 from the dichroic element 120, and the light homogenizing element 140 has a light incident end 141. In the embodiment, the lens array 150 may use only a single group and be disposed on the transmission path of the exciting beam L1. The lens array 150 includes a plurality of lens units 151.

FIG. 2 is a schematic diagram of a light incident end of the light homogenizing element in FIG. 1, and FIG. 3 is a schematic diagram of light spots formed by the exciting beam in the lens array according to an embodiment of the invention. Referring to FIGS. 1, 2 and 3, in the embodiment, the long side 151a of each lens unit 151 is parallel to the long side 141b of the light incident end 141 when being projected to the light incident end 141 along the transmission path of the converted beam L2. Since the lens array 150 shapes the incident exciting beam L1, the exciting beam L1 forms the light spots S3 in the lens array 150 and each light spot S3 may cover at least two lens units 151, so that the light spot of the exciting beam L1 emitted from the lens array 150 corresponds to the shape of the lens unit 151. As such, the long side of the light spot of the converted beam L2 at the light incident end 141 is parallel to the long side 141b of the light incident end 141.

Referring to FIGS. 1 and 3, in the embodiment, the exciting light source 111 is, for example, a laser light source or other solid state light sources, but not limited thereto. The exciting light sources 111 are arranged in an array, for example. The number of the exciting light sources 111 in the embodiment is twenty as an example, and thus twenty light spots S3 are formed on the lens array 150. In addition, the exciting light source module 110 may further include a plurality of collimating lenses 112 respectively disposed in front of the exciting light sources 111, that is, the collimating lens 112 is located between the exciting light source 111 and the lens array 150. The collimating lenses 112 are used to transmit the exciting beam L1 to the dichroic element 120. In another embodiment, the collimating lenses 112 may be replaced with a lens array.

The dichroic element 120 is, for example, a dichroic filter or a dichroic mirror, but not limited thereto. The dichroic element 120 is used to allow the exciting beam L1 (e.g., a blue beam) to pass therethrough and reflect the converted beam L2 (e.g., a yellow beam). In another embodiment of the illumination system, the dichroic element 120 may reflect the exciting beam L1 and allow the converted beam L2 to pass therethrough, but the optical architecture of the illumination system needs to be properly adjusted.

The wavelength-converting element 130 is disposed with a wavelength-converting material (not labeled), and the wavelength-converting material may be a photoluminescent material for receiving a short wavelength beam and generating a corresponding converted beam L2 through the photoluminescence phenomenon (see FIG. 1). The photoluminescent material is, for example, a phosphor, and the wavelength-converting element 130 is, for example, a phosphor wheel. The phosphor wheel has a phosphor block (not shown), and the exciting beam L1 irradiates the phosphor block to excite the converted beam L2.

The light homogenizing element 140 is, for example, a light integration rod, but not limited thereto. The light integrating rod can be a solid cylinder or a hollow cylinder.

The lens array 150 of the embodiment is, for example, disposed between the exciting light source module 110 and the dichroic element 120 and is located on the transmission path of the exciting beam L1. Each lens unit 151 of the lens array 150 has, for example, a positive refractive power. For example, each lens unit 151 may be a plano-convex lens, a biconvex lens, or the like. In another embodiment, each lens unit 151 may have a negative refractive power according to the requirements. For example, each lens unit 151 may be a biconcave lens. In addition, the exciting beams L1 from the exciting light sources 111 form a plurality of light spots S3 on the lens array 150, and each light spot S3 covers at least two lens units 151, for example. Since the energy concentration of the light spot S3 of the exciting beam L1 is high, when at least two lens units 151 are covered, each covered lens unit 151 cuts the light spot S3 and then projects it to the wavelength-converting element 130 to avoid excessive concentration of energy, thereby forming an overall light spot with better uniformity on the wavelength-converting element 130.

In order to allow most of the converted beam L2 to enter the light homogenizing element 140 from the light incident end 141, the element structure of the illumination system 100 may be adjusted. Specifically, the shape of the exciting beam L1 may be changed by each lens unit 151 of the lens array 150, and the shape of the converted beam L2 converted by the wavelength-converting element 130 matches the shape of the light incident end 141 of the light homogenizing element 140. For example, the shape of each lens unit 151 is a rectangle corresponding to the shape of the light incident end 141 of the light homogenizing element 140, and the aspect ratio of each lens unit 151 is greater than the aspect ratio of the light incident end 141 of the light homogenizing element 140. The relationship between the aspect ratio of each lens unit 151 and the aspect ratio of the light incident end 141 of the light homogenizing element 140 will be exemplified below.

FIG. 4 is a schematic diagram of a light spot of an exciting beam and a converted beam on a wavelength-converting element according to an embodiment of the invention. Referring to FIGS. 2 and 4, assuming that the light incident end 141 of the light homogenizing element 140 is rectangular, the size of the light incident end 141 is 2.5 mm×4.6 mm and the light-spot magnification of the wavelength-converting element 130 to the light homogenizing element 140 is two, therefore, it is necessary to preset the size of the light spot S2 of the converted beam L2 on the wavelength-converting element 130 to be 1.25 mm×2.3 mm (the aspect ratio is 2.3/1.25=1.84). In addition, when the exciting beam L1 is projected onto the surface (not labeled) of the wavelength-converting material of the wavelength-converting element 130, the exciting beam L1 forms an overall light spot S1 on the surface and the converted beam L2 converted by the exciting beam L1 entering the wavelength-converting material is scattered around, so that the light spot S2 when the converted beam L2 exits the surface of the wavelength-converting material of the wavelength-converting element 130 is greater than the overall light spot S1 where the exciting beam L1 converges on the wavelength-converting element 130. That is, the length of the overall light spot S1 of the exciting beam L1 on the wavelength-converting element 130 is less than the length of the light spot S2 of the converted beam L2 on the wavelength-converting element 130. Assuming that the length and the width of the light spot S2 of the converted beam L2 on the wavelength-converting element 130 are both increased by 0.25 mm, therefore, it is necessary to preset the size of the overall light spot S1 of the exciting beam L1 on the wavelength-converting element 130 to be 1 mm×2.05 mm (the aspect ratio is 2.05) so as to cause the size of the light spot S2 of the converted beam L2 on the wavelength-converting element 130 to be 1.25 mm×2.3 mm. Therefore, the aspect ratio of the overall light spot S1 where the exciting beam L1 converges to the wavelength-converting element 130 needs to be greater than the aspect ratio of the light spot S2 of the converted beam L2 on the wavelength-converting element 130.

In the embodiment, the entire exciting beam L1 is converged on the surface of the wavelength-converting material of the wavelength-converting element 130 by the lens array 150 to form the overall light spot S1 and the long side 151a of each lens unit 151 is parallel to the long side 141b of the light incident end 141 when being projected onto the light incident end 141 along the transmission path of the converted beam L2, so that the long side L2c of the light spot S2 of the converted beam L2 at the light incident end 141 is parallel to the long side 141b of the light incident end 141. Since the aspect ratio of each lens unit 151 is substantially equal to the aspect ratio of the overall light spot S1 of the exciting beam L1 on the wavelength-converting element 130, the aspect ratio of each lens unit 151 needs to be greater than the aspect ratio of the light incident end 141 of the light homogenizing element 140 in design, so that most of the converted beam L2 enters the light homogenizing element 140 from the light incident end 141 to reduce light loss. The above-mentioned numerical values are only for examples, and a person skilled in the art to which the invention pertains may use a suitable aspect ratio of each lens unit 151 according to the difference in design values of various elements in the illumination system 100.

The illumination system 100 may further include a plurality of lenses or other optical elements such as a first condenser lens 160, a second condenser lens 170 and a third condenser lens 180. The first condenser lens 160 is disposed between the exciting light source module 110 and the dichroic element 120. The second condenser lens 170 is disposed between the lens array 150 and the wavelength-converting element 130. The third condenser lens 180 is disposed between the dichroic element 120 and the light homogenizing element 140. In the embodiment of FIG. 1, the first condenser lens 160 is located between the exciting light source module 110 and the lens array 150, the second condenser lens 170 is located between the dichroic element 120 and the wavelength-converting element 130, so that the exciting beam L1 sequentially passes through the first condenser lens 160, the lens array 150, the dichroic element 120 and the second condenser lens 170 and converges on the wavelength-converting element 130.

In the illumination system 100 of the embodiment, the shape of the overall light spot S1 formed by the exciting beam L1 on the wavelength-converting element 130 is changed by each lens unit 151 of the lens array 150, so that the shape of the light spot S2 of the converted beam L2 on the wavelength-converting element 130 marches with the shape of the light incident end 141 of the light homogenizing element 140, thereby reducing the light loss when the converted beam L2 enters the light homogenizing element 140 via the light incident end 141 and improving the light utilization efficiency.

In addition, the wavelength-converting element 130 may also allow the exciting beam L1 to pass therethrough, and the exciting beam L3 will be used to represent the exciting beam L1 passing through the wavelength-converting element 130 in the following. Specifically, the wavelength-converting element 130 is, for example, a phosphor wheel and has a phosphor block (not shown) and a light transmission block (not shown). When the wavelength-converting element 130 rotates, the exciting beam L1 irradiates the phosphor block and the light transmission block in turn. The exciting beam L1 irradiating the phosphor block is converted into the converted beam L2, and the exciting beam L1 irradiating the light transmission block and passing through the wavelength-converting element 130 is the exciting beam L3. In an embodiment, the exciting beam L1 is, for example, a blue beam, and the converted beam L2 is, for example, a yellow beam. In addition, the phosphor block can also have a plurality of phosphors that can generate different colors, so that the converted beam L2 is divided into a plurality of colors according to the time sequence. In addition, the illumination system 100 may further include a light guide assembly 190, and the exciting beam L3 passing through the wavelength-converting element 130 is guided by the light guide assembly 190 and transmitted to the light homogenizing element 140. The light guide assembly 190 includes, for example, three reflective elements 191, 192 and 193 to sequentially reflect the exciting beam L3 and guide it back to the dichroic element 120. The exciting beam L3 passes through the dichroic element 120 and is then transmitted to the light homogenizing element 140.

Although the embodiment of the invention is an example in which the phosphor wheel has a light transmission block, the architecture of the illumination system of the invention is not limited thereto. In another embodiment, the phosphor wheel may have a phosphor block (not shown) and a reflective block (not shown). The reflective block may be used to reflect the exciting beam, and then with other elements of the illumination system to cause the exciting beam reflected by the reflective block and the converted beam to enter the light homogenizing element.

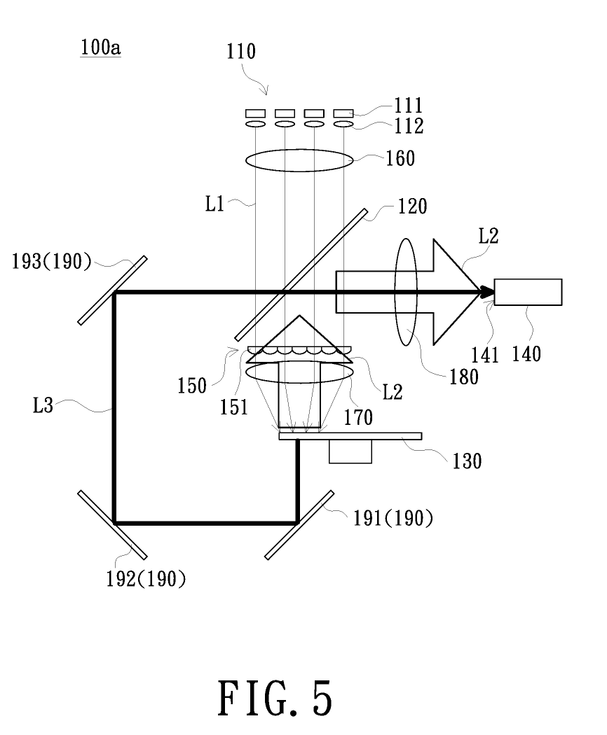

FIG. 5 is a schematic diagram of an illumination system according to another embodiment of the invention. Referring to FIG. 5, the structure and advantages of the illumination system 100a of the embodiment is similar to those of the illumination system 100, and only the main difference of the structure will be described below. The lens array 150 of the illumination system 100a of the embodiment is disposed between the dichroic element 120 and the wavelength-converting element 130. The shape of each lens unit 151 is, for example, a rectangle corresponding to the shape of the light incident end 141 of the light homogenizing element 140. Since the exciting beam L1 and the converted beam L2 both pass through the lens array 150, the aspect ratio of each lens unit 151 can be designed to be substantially equal to the aspect ratio of the light incident end 141 of the light homogenizing element 140, so that the shape of the light spot of the converted light L2 at the light incident end 141 of the light homogenizing element 140 matches the shape of the light incident end 141, thereby reducing light loss when the converted beam L2 enters the light homogenizing element 140 from the light incident end 141 and improving light utilization efficiency.

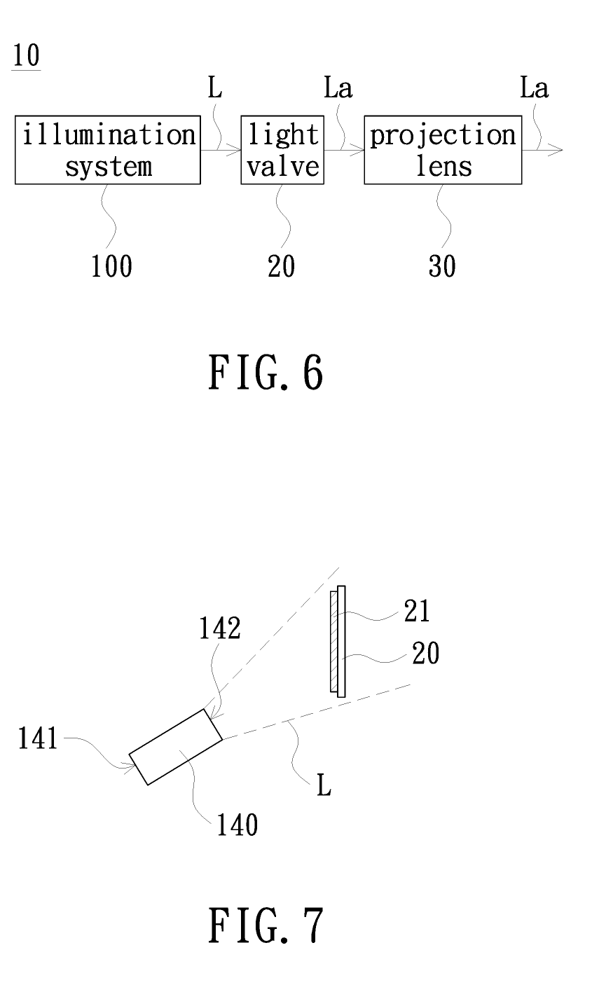

FIG. 6 is a block diagram of a projection apparatus according to an embodiment of the invention. Referring to FIG. 6, the projection apparatus 10 of the embodiment includes the above-described illumination system 100, a light valve 20 and a projection lens 30. The illumination system 100 is used to provide the illumination beam L. The light valve 20 is disposed on the transmission path of the illumination beam L to convert the illumination beam L into the image beam La. The projection lens 30 is disposed on the transmission path of the image beam La to project the image beam La onto the screen, thereby forming an image on the screen. The illumination beam L includes the above-described converted beam L2 and exciting beam L3. The illumination system 100 may also include a color wheel (not shown) to divide the illumination beam L into three beams of more pure red, green and blue colors. The light valve 20 may be a transmissive light valve or a reflective light valve, wherein the transmissive light valve may be a liquid crystal display panel and the reflective light valve may be a digital micro-mirror device (DMD) or liquid crystal on silicon (LCoS) panel. According to different design architectures, the number of light valves 20 may be one or more. In addition, the illumination beam L can be incident on the light valve 20 in a forward direction or obliquely incident on the light valve 20.

FIG. 7 is a schematic diagram of a light homogenizing element and a light valve according to an embodiment of the invention. Referring to FIGS. 6 and 7, the light homogenizing element 140 in the embodiment has a light exiting end 142 opposite to the light incident end 141. The illumination beam L exiting from the light exiting end 142 is, for example, obliquely incident on the light modulation area 21 of the light valve 20. The light modulation area 21 is an effective area where the light valve 20 can convert the illumination beam L into the image beam La. Taking the light valve 20 as a digital micro-mirror element as an example, the light modulation area 21 is an area where a plurality of micro-mirrors are disposed.

In the embodiment, the light exiting end 142 of the light homogenizing element 140 and the light modulation area 21 are, for example, rectangular, and the aspect ratio of the light exiting end 142 of the light homogenizing element 140 may be adjusted to be greater than the aspect ratio of the light modulation area 21, so that most of the illumination beam L can be irradiated on the light modulation area 21 of the light valve 20 to increase light utilization efficiency. Therefore, the aspect ratio of the light incident end 141 of the light homogenizing element 140 may be different from the aspect ratio of the light exiting end 142.

In summary, in the embodiment of the invention, since a single lens array is adopted, the shape of light spot when the exciting beam exiting the lens array is irradiated to the wavelength-converting element can be adjusted, so that the shape of the light spot of the converted beam converted by the wavelength-converting element corresponds to the shape of the light incident end of the light homogenizing element, thereby improving the light utilization efficiency. The projection apparatus of the embodiment of the invention can improve the light utilization efficiency because of using the above illumination system.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims. Furthermore, the terms such as the first stop part, the second stop part, the first ring part and the second ring part are only used for distinguishing various elements and do not limit the number of the elements.

What is claimed is:

1. An illumination system, comprising:
an exciting light source module, a dichroic element, a wavelength-converting element, a light homogenizing element and a lens array, wherein
the exciting light source module comprises a plurality of exciting light sources, and each of the plurality of exciting light sources is used to provide an exciting beam;
the dichroic element is disposed on a transmission path of the exciting beam and used to allow the exciting beam from the exciting light source module to be transmitted to the wavelength-converting element;
the wavelength-converting element is disposed on a transmission path of the exciting beam from the dichroic element to convert the exciting beam into a converted beam and reflect the converted beam to the dichroic element, and the dichroic element is used to transmit the converted beam to the light homogenizing element;
the light homogenizing element is disposed on a transmission path of the converted beam from the dichroic element, and the light homogenizing element has a light incident end; and
the lens array is disposed on a transmission path of the exciting beam, the lens array comprises a plurality of lens units, and a long side of each of the plurality of lens units is parallel to a long side of the light incident end when being projected along the transmission path of the converted beam to the light incident end.

2. The illumination system according to claim 1, wherein the lens array is disposed between the exciting light source module and the dichroic element.

3. The illumination system according to claim 2, wherein a shape of each of the plurality of lens units is a rectangle corresponding to a shape of the light incident end of the light homogenizing element, and an aspect ratio of each of the plurality of lens units is greater than an aspect ratio of the light incident end of the light homogenizing element.

4. The illumination system according to claim 3, wherein the exciting beam is converged on the wavelength-converting element by the lens array to form an overall light spot, and the aspect ratio of each of the plurality of lens units is equal to an aspect ratio of the overall light spot of the exciting beam on the wavelength-converting element.

5. The illumination system according to claim 3, an aspect ratio of an overall light spot of the exciting beam converged to the wavelength-converting element is greater than the aspect ratio of the light spot of the converted beam on the wavelength-converting element, and a length of the overall light spot of the exciting beam on the wavelength-converting element is less than a length of the light spot of the converted beam on the wavelength-converting element.

6. The illumination system according to claim 2, further comprising:
a first condenser lens, disposed between the exciting light source module and the lens array;
a second condenser lens, disposed between the dichroic element and the wavelength-converting element; and
a third condenser lens, disposed between the dichroic element and the light homogenizing element.

7. The illumination system according to claim 1, wherein the lens array is disposed between the dichroic element and the wavelength-converting element.

8. The illumination system according to claim 7, wherein a shape of each of the plurality of lens units is a rectangle corresponding to a shape of the light incident end of the light homogenizing element, and an aspect ratio of each of the plurality of lens units is equal to an aspect ratio of the light incident end of the light homogenizing element.

9. The illumination system according to claim 8, wherein the exciting beam is converged on the wavelength-converting element by the lens array to form an overall light spot, and the aspect ratio of each of the plurality of lens units is equal to an aspect ratio of the overall light spot of the exciting beam on the wavelength-converting element.

10. The illumination system according to claim 7, further comprising:
a first condenser lens, disposed between the exciting light source module and the lens array;
a second condenser lens, disposed between the lens array and the wavelength-converting element; and
a third condenser lens, disposed between the dichroic element and the light homogenizing element.

11. The illumination system according to claim 1, wherein a light spot of each of the exciting beams on the lens array covers at least two of the plurality of lens units.

12. The illumination system according to claim 1, wherein the exciting light source module comprises a plurality of collimating lenses respectively disposed in front of the plurality of exciting light sources and used to transmit the exciting beam to the dichroic element.

13. The illumination system according to claim 1, wherein the wavelength-converting element is used to allow the exciting beam to pass therethrough, the illumination system further comprises a light guide assembly, and the exciting beam passing through the wavelength-converting element is guided by the light guide assembly and transmitted to the light homogenizing element.

14. A projection apparatus, comprising:
an illumination system, used to provide an illumination beam and comprising an exciting light source module, a dichroic element, a wavelength-converting element, a light homogenizing element and a lens array, wherein
the exciting light source module comprises a plurality of exciting light sources, and each of the plurality of exciting light sources is used to provide an exciting beam;
the dichroic element is disposed on a transmission path of the exciting beam and used to allow the exciting beam from the exciting light source module to be transmitted to the wavelength-converting element;
the wavelength-converting element is disposed on a transmission path of the exciting beam from the dichroic element to convert the exciting beam into a converted beam and reflect the converted beam to the dichroic element, and the dichroic element is used to transmit the converted beam to the light homogenizing element;
the light homogenizing element is disposed on a transmission path of the converted beam from the dichroic element, and the light homogenizing element has a light incident end; and
the lens array is disposed on a transmission path of the exciting beam, the lens array comprises a plurality of lens units, and a long side of each of the plurality of lens units is parallel to a long side of the light incident end when being projected along the transmission path of the converted beam to the light incident end;
a light valve, disposed on a transmission path of the illumination beam to convert the illumination beam into an image beam; and
a projection lens, disposed on a transmission path of the image beam.

15. The projection apparatus according to claim 14, wherein the light homogenizing element has a light exiting end opposite to the light incident end, the illumination beam exiting from the light exiting end is obliquely incident on a light modulation area of the light valve, the light exiting end and the light modulation area are rectangular, and an aspect ratio of the light exiting end of the light homogenizing element is greater than an aspect ratio of the light modulation area.

16. The projection apparatus according to claim 14, wherein the lens array is disposed between the exciting light source module and the dichroic element.

17. The projection apparatus according to claim 16, wherein a shape of each of the plurality of lens units is a rectangle corresponding to a shape of the light incident end of the light homogenizing element, and an aspect ratio of each of the plurality of lens units is greater than an aspect ratio of the light incident end of the light homogenizing element.

18. The projection apparatus according to claim 14, wherein the lens array is disposed between the dichroic element and the wavelength-converting element.

19. The projection apparatus according to claim 18, wherein a shape of each of the plurality of lens units is a rectangle corresponding to a shape of the light incident end of the light homogenizing element, and an aspect ratio of each of the plurality of lens units is equal to an aspect ratio of the light incident end of the light homogenizing element.

20. The projection apparatus according to claim 14, wherein a light spot of each of the exciting beams on the lens array covers at least two of the plurality of lens units.
